(19) United States
(12) Patent Application Publication
(10) Pub. No.: US 2022/0158420 A1
(43) Pub. Date: May 19, 2022

(54) INTEGRATED WHOLE HOUSE ELECTRICAL SYSTEMS

(71) Applicant: IP FACTORS, LLC, Los Angeles, CA (US)

(72) Inventor: Farhad Vafaee, Los Angeles, CA (US)

(21) Appl. No.: 17/527,694

(22) Filed: Nov. 16, 2021

Related U.S. Application Data
(60) Provisional application No. 63/114,323, filed on Nov. 16, 2020.
(60) Provisional application No. 63/114,341, filed on Nov. 16, 2020.
(60) Provisional application No. 63/114,349, filed on Nov. 16, 2020.
(60) Provisional application No. 63/114,390, filed on Nov. 16, 2020.
(60) Provisional application No. 63/114,401, filed on Nov. 16, 2020.
(60) Provisional application No. 63/114,408, filed on Nov. 16, 2020.
(60) Provisional application No. 63/114,417, filed on Nov. 16, 2020.
(60) Provisional application No. 63/114,426, filed on Nov. 16, 2020.
(60) Provisional application No. 63/114,452, filed on Nov. 16, 2020.
(60) Provisional application No. 63/114,460, filed on Nov. 16, 2020.
(60) Provisional application No. 63/114,468, filed on Nov. 16, 2020.
(60) Provisional application No. 63/114,472, filed on Nov. 16, 2020.
(60) Provisional application No. 63/114,476, filed on Nov. 16, 2020.
(60) Provisional application No. 63/114,485, filed on Nov. 16, 2020.
(60) Provisional application No. 63/114,489, filed on Nov. 16, 2020.
(60) Provisional application No. 63/114,492, filed on Nov. 16, 2020.
(60) Provisional application No. 63/115,497, filed on Nov. 18, 2020.
(60) Provisional application No. 63/114,755, filed on Nov. 17, 2020.

(51) Int. Cl. H02B 1/04; H02B 1/40; H02G 3/10; F21V 23/02; F21S 8/00

(52) U.S. Cl. CPC H02B 1/04; H02B 1/40; F21S 8/00; F21V 23/02; H02G 3/10

(57) ABSTRACT

An electrical system for installation in a building project includes an electrical panel assembly with a chassis and at least one housing and one or more line voltage source connection points mounted to the chassis. The system also includes one or more low voltage power sources mounted to the chassis, wherein the electrical panel assembly is located in a predetermined location in the building project for connection to one or more low voltage components via direct connections and to one or more line voltage outlets.

### CROSS-REFERENCE TO RELATED APPLICATIONS

This application claims the benefit of U.S. Provisional Application No. 63/114,323, filed on Nov. 16, 2020, U.S. Provisional Application No. 63/114,341, filed on Nov. 16, 2020, U.S. Provisional Application No. 63/114,349, filed on Nov. 16, 2020, U.S. Provisional Application No. 63/114,390, filed on Nov. 16, 2020, U.S. Provisional Application No. 63/114,401, filed on Nov. 16, 2020, U.S. Provisional Application No. 63/114,408, filed on Nov. 16, 2020, U.S. Provisional Application No. 63/114,417, filed on Nov. 16, 2020, U.S. Provisional Application No. 63/114,426, filed on Nov. 16, 2020, U.S. Provisional Application No. 63/114,452, filed on Nov. 16, 2020, U.S. Provisional Application No. 63/114,460, filed on Nov. 16, 2020, U.S. Provisional Application No. 63/114,468, filed on Nov. 16, 2020, U.S. Provisional Application No. 63/114,472, filed on Nov. 16, 2020, U.S. Provisional Application No. 63/114,476, filed on Nov. 16, 2020, U.S. Provisional Application No. 63/114,485, filed on Nov. 16, 2020, U.S. Provisional Application No. 63/114,489, filed on Nov. 16, 2020, U.S. Provisional Application No. 63/114,492, filed on Nov. 16, 2020, U.S. Provisional Application No. 63/115,497, filed on Nov. 18, 2020, and U.S. Provisional Application No. 63/114,755, filed on Nov. 17, 2020. The entire disclosures of each of the above applications are incorporated herein by reference.

### FIELD

The present disclosure relates to integrated whole house electrical systems for construction projects. Such whole house electrical systems can be used for example in the context of Integrated Component-Based Construction (ICBC) methods.

### BACKGROUND

This section provides background information related to the present disclosure which is not necessarily prior art.

Traditional construction methods and related systems often include the preparation of a design and then the use of general contractors and/or skilled trades people to build the construction project based on the design. The contractors and skilled trades people often possess industry and trade knowledge and skills that enable such individuals to perform the necessary steps to complete the construction project efficiently and adequately to meet various requirements for the project such as price, timing, function, zoning, safety, durability and the like. The building materials used during construction projects using such traditional methods and systems often are sourced from a variety of vendors, suppliers and manufacturers that may have purchasing programs or relationships with the traditional contractors and/or trades people.

These traditional construction methods and systems, however, suffer from problems and drawbacks. For example, such traditional construction methods and systems require the individualized and/or specialized knowledge of the contractors and/or skilled tradespeople. Without such individuals, such as during labor shortages, increases in building demand or in geographic areas without such individuals, construction projects can be difficult to complete. Furthermore, when the availability of individuals with sufficient knowledge and skill is low, the quality, price, durability and safety of construction projects can suffer. Still further, the availability, timing and delivery of construction building materials can be slow, costly and inefficient using traditional supply chains that use traditional building material suppliers, vendors and manufacturers.

In other existing construction methods and systems, pre-fabricated construction projects can allow for all or portions of a construction project to be performed remote from a construction site. Such pre-fabricated construction projects or portions thereof can then be transported from the building location to the construction site. Such pre-fabricated construction methods and systems also suffer from problems and drawbacks. For example, existing pre-fabricated construction methods and systems often allow only for minor variation between construction projects such that the construction projects lack differentiation, personalization and/or the like. Another drawback is that there are limitations on what size, shape, weight and/or configuration can be transported from a building location to a construction site.

Therefore, there exists a need for improved construction methods and systems that address the problems and drawbacks of existing processes.

### SUMMARY

This section provides a general summary of the disclosure, and is not a comprehensive disclosure of its full scope or all of its features.

In some embodiments in accordance with the present disclosure, an electrical system for installation in a building project may include an electrical panel assembly comprising a chassis and at least one housing and one or more line voltage source connection points mounted to the chassis. The system may also include one or more low voltage power sources mounted to the chassis. The electrical panel assembly may be located in a predetermined location in the building project for connection to one or more low voltage components via direct connections and to one or more line voltage outlets.

In one aspect, the direct connections are home-run connections.

In another aspect, the at least one housing may be configured to receive an electrical input from an exterior of the building project and the electrical system further includes one or more wireless smart switches mounted to the chassis and coupled to the one or more low voltage power sources.

In another aspect, the at least one housing may be configured to receive an electrical input from an exterior of the building project and the one or more low voltage power sources may include one or more transformers electrically coupled to the electrical input.

In another aspect, the line voltage source connection points may include an electrical voltage of about 120 volts or about 240 volts.

In another aspect, the low voltage power sources may include an electrical voltage of about 12 volts or about 24 volts.

In another aspect, the predetermined location in the building project may include a location of a pre-fabricated core and the electrical panel assembly is a pre-fabricated assembly that is delivered to the building project as part of the pre-fabricated core that includes one or more other distribution systems for the building project.

In another aspect, each of the direct connections may include a length of wire that extends from one of the one or more low voltage components to the electrical panel assembly without interruption.

In another aspect, the one or more low voltage components may include one or more low voltage lights.

In another aspect, the electrical system may include one or more wireless switches mounted to the chassis and coupled to the one or more low voltage components.

In another aspect, the electrical system may include a battery coupled to the electrical panel assembly configured to energize the one or more low voltage components.

In some embodiments in accordance with the present disclosure, a pre-fabricated electrical panel assembly may include a chassis and an electrical resource input receptacle mounted to the chassis configured to receive an electrical resource input to provide electrical power to a building project. The panel assembly may also include one or more line voltage source connection points mounted to the chassis electrically coupled to the electrical resource input receptacle and one or more low voltage power sources mounted to the chassis electrically coupled to the electrical resource input receptacle and configured for direct connection of a low voltage component.

In one aspect, the direct connection of the low voltage component is an uninterrupted wire connected between the low voltage component and the electrical panel assembly.

In another aspect, the electrical panel assembly also includes one or more wireless smart switches coupled to the one or more low voltage power sources.

In another aspect, the one or more wireless smart switches are mounted to the chassis.

In another aspect, no low voltage connections are connected to the electrical panel assembly via an indirect connection.

In another aspect, the chassis may include one or more support members and is configured to mount to a wall of a predetermined size.

In some embodiments in accordance with the present disclosure, a building project may include an electrical system to provide line voltage outlets and low voltage lighting. The building project may include a pre-fabricated electrical panel assembly with a plurality of line voltage connection points, a plurality of wireless switches and a plurality of low voltage transformers. The building project may also include a plurality of line voltage outlets each connected to one of the plurality of line voltage connection points and a plurality of low voltage lighting components each connected to one of the plurality of low voltage transformers via direct electrical connections.

In one aspect, the pre-fabricated electrical panel assembly is assembled prior to delivery to a building site for the building project.

In another aspect, the building project does not include a low voltage lighting component that is connected to the electrical panel assembly via an indirect connection.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is an illustration of a construction environment in which the integrated whole house electrical systems of the present disclosure can be used.

FIG. 2 is an illustration of an example centralized construction model in a semi-exploded view.

FIG. 3 is an illustration of the centralized construction model of FIG. 2 showing further individual components.

FIG. 4 is an illustration of example building project includes the integrated whole house electrical systems of the present disclosure.

FIG. 5 is an illustration of an example construction plan using in connection with the systems and methods of the present disclosure.

FIG. 6 is a block diagram showing aspects of an example integrated whole house electrical system of the present disclosure.

FIG. 7 is a sectional view of an example core that can include portions of the integrated whole house electrical systems of the present disclosure.

FIG. 8 is an illustration of an example electrical panel assembly in accordance with some embodiments of the present disclosure.

Corresponding reference numerals indicate corresponding parts throughout the several views of the drawings.

### DETAILED DESCRIPTION

Example embodiments will now be described more fully with reference to the accompanying drawings. For purposes of the description hereinafter, it is to be understood that the embodiments described below may assume alternative variations and embodiments. It is also to be understood that the specific articles, compositions, and/or processes described herein are exemplary and should not be considered as limiting. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. The terms “couple,” “coupled,” “operatively coupled,” “operatively connected,” and the like should be broadly understood to refer to connecting devices or components together either mechanically, electrically, wired, wirelessly, or otherwise, such that the connection allows the pertinent devices or components to operate (e.g., communicate) with each other as intended by virtue of that relationship.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

In the present disclosure the singular forms “a,” “an,” and “the” include the plural reference, and reference to a particular numerical value includes at least that particular value, unless the context clearly indicates otherwise. When values are expressed as approximations, by use of the antecedent “about,” it will be understood that the particular value forms another embodiment. As used herein, “about X” (where X is a numerical value) preferably refers to ±10% of the recited value, inclusive. For example, the phrase “about 8” preferably refers to a value of 7.2 to 8.8, inclusive. Where present, all ranges are inclusive and combinable. For example, when a range of “1 to 5” is recited, the recited range should be construed as including ranges “1 to 4”, “1 to 3”, “1-2”, “1-2 & 4-5”, “1-3 & 5”, “2-5”, and the like. In addition, when a list of alternatives is positively provided, such listing can be interpreted to mean that any of the alternatives may be excluded, e.g., by a negative limitation in the claims. For example, when a range of “1 to 5” is recited, the recited range may be construed as including situations whereby any of 1, 2, 3, 4, or 5 are negatively excluded; thus, a recitation of “1 to 5” may be construed as “1 and 3-5, but not 2”, or simply “wherein 2 is not included.” It is intended that any component, element, attribute, or step that is positively recited herein may be explicitly excluded in the claims, whether such components, elements, attributes, or steps are listed as alternatives or whether they are recited in isolation.

The integrated whole house electrical systems and aspects thereof are improvements over known or traditional construction methods that employ discreet installation of electrical components and systems that are often complicated, require specialized knowledge and the consultation of complicated schematics and drawings. The electrical system of the present disclosure are integrated in that the entire system is designed using a library of components and with the entire structure of the building project in mind. Various electrical components can arrive at the building site pre-fabricated or pre-installed in wall sections, in a pre-fabricated core or as simple ready to install components. The components can arrive with unique identifying markings or labels to identify to the builder where such components should be installed in the building project without the need to consult complicated electrical schematics or drawings and without specialized electrical knowledge or without knowledge of complicated local zoning requirements. A construction plan can have taken all such knowledge and requirements into account and provide the systems and components to the building site just-in-time for simple installation.

The integrated whole house electrical systems can include, for example, a centralized electrical panel assembly to which all or most electrical systems of the building project can be connected. As will be further described, the centralized electrical panel assembly can include an electrical panel source box that can serve as the connection point from a public source or external source of electricity. The electrical panel assembly can also include gang boxes, electric switches and electrical transformers. The gang boxes can serve as connection points for line voltage connections that can be positioned throughout the building project. The electrical transformers can provide low voltage power (e.g., 12 V-24 V) to power low voltage lighting for the interior and exterior of the building project. The electrical switches can be paired with the electrical transformers and can be used to control and/or energize the low voltage components. Each electrical component, whether a line voltage outlet, interior lighting component or the like, can be connected to the electrical panel assembly with suitable wiring. The wiring can be installed as a home-run connection, that is, a wire that runs from the electrical component to the electrical panel without interruption (e.g., without connecting other electrical components, or without being spliced or connected to wiring of other electrical components). In this manner, the electrical connection is simple and standard for every connection making installing simple without the need for specialized knowledge of consulting specialized drawings. To further simplify, the controls for various electrical components such as lighting, interior fans, and the like can be installed as wireless control points or can be controlled via a mobile computing device so that no wiring is required between the control points and the electrical components.

As can be appreciated, this simplified and integrated whole electrical systems of the present disclosure can result in improvements in efficiency, complexity and requires less reliance on specialized knowledge and the consultation of complicated schematics and drawings. The building projects that use the systems and methods of the present disclosure can be completed more quickly and can be easily scaled in due to the reduced reliance on specialized knowledge and labor. Still further, the building projects of the present disclosure can be easily maintained and repaired given the simplified, standardized and integrated electrical systems.

In some examples, the methods and systems of the present disclosure may be used to construct residential building projects. In other examples, the methods and systems of the present disclosure can be used to construction other projects such as commercial or public building projects.

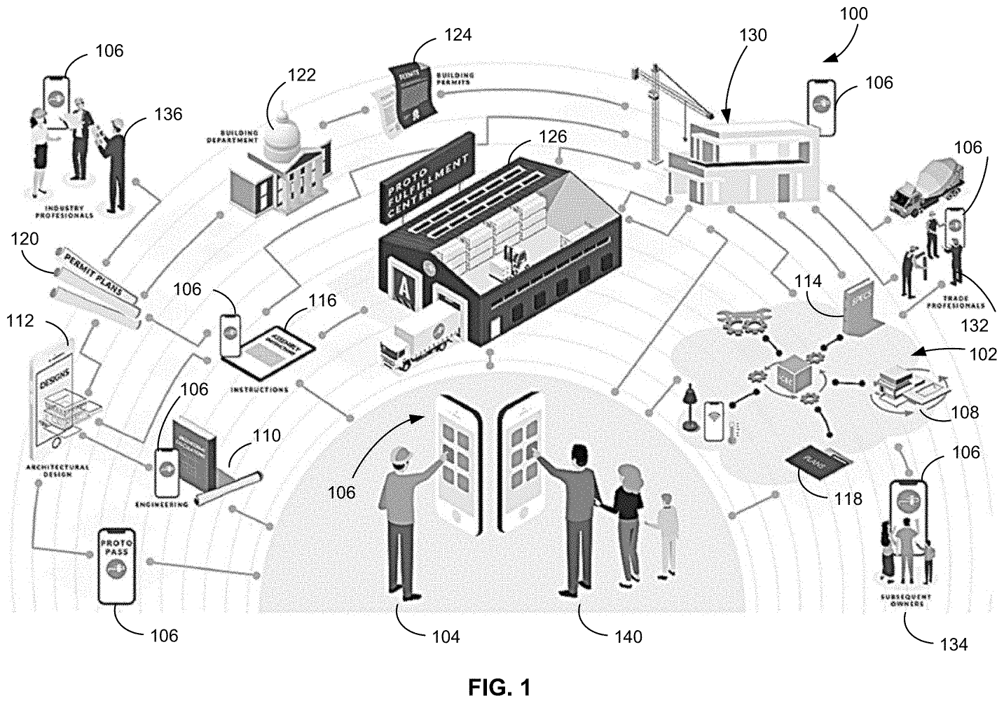

Referring now to FIG. 1, a construction environment 100 is shown. FIG. 1 illustrates an example environment 100 in which the electrical system(s) can be utilized. As shown, a user 140 or builder/contactor 104 can interact with a coordination platform 102 using a construction application 106. As indicated by the mobile phone icon, the various stakeholders in the environment 100 can also interact with the coordination platform 102 either directly or indirectly via a communication network, not shown. The coordination platform 102 can operate to share information and provide access to information during various stages of the construction process.

After a user (e.g., a contractor/builder or customer) engages with the construction system, the entire construction process can be managed and synchronized using the coordination platform 102. During the initial stages, the construction project can be designed and engineered by affiliate service providers 112, 110, respectively. The construction project design can be translated or embodied in a centralized 3D construction model 108 that can be stored in the coordination platform 102. The centralized 3D model 108 can be used to create all documentary information such as design specifications 114, drawings, renderings, etc. This documentation can then be used to create permit plans 120 and shared with other industry professionals 136 and submitted to regulatory authority 122 to obtain the permits 124 required to begin and/or execute the construction project.

The coordination platform 102 can also coordinate and determine a construction plan 118 that can include assembly instructions 116 and can group and allocate the building components and materials into stages, groups or “factors” for the construction of the construction project. As determined by the construction plan 118 and the determined factors, fabrication data, assembly data and/or factor data can be shared with fulfillment center 126 for the manufacturing, fabrication and delivery of the components and materials to the building site 130. Various trade professionals can use the delivered components and materials to complete the factors as scheduled and coordinated by the coordination platform 102. While all these actions are occurring the fulfillment centers 126 and the trade professionals can be interacting with the coordination platform 102 to provide updates on status and progress on completion of tasks. With this information, the coordination platform 102 can share and/or allow access to status information to users such as general contractors 104 and/or customers 140.

Once the construction project is complete, the coordination platform 102 can also serve as an information repository for construction, maintenance and repair information for the subsequent owners 134 of the construction project 130.

As can be seen, the construction systems of the present disclosure and aspects thereof, such as coordination platform 102 provide improvements in efficiency, information sharing, coordination of information and construction tasks over known systems and methods. Furthermore, the construction systems of the present disclosure can provide further added value by serving as information sources regarding the construction, maintenance and repair of construction projects that were built using the construction system(s). Construction systems such as those that can be used with the electrical system(s) of the present disclosure are further detailed in U.S. Pat. Appl. No. TBD, filed on Nov. 16, 2021 entitled SYSTEMS AND METHODS FOR INTEGRATED COMPONENT-BASED CONSTRUCTION, the entirety of which is hereby incorporated by reference.

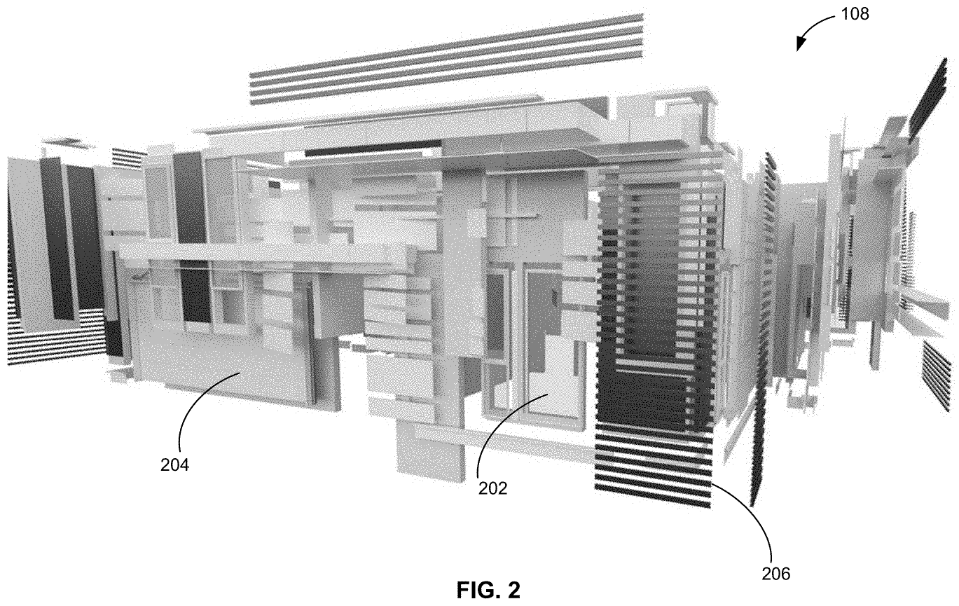

The coordination platform 102 can store and access information in the form of a centralized 3D construction model 108. The construction model 108 can be can be a 3D parametric model that includes each of the components and/or products that may be used to build the construction project 130. As shown in FIG. 2, the construction model 108 may allow a user to view and/or extract the information regarding the various components that are used to build the construction project. As shown in FIG. 2, the construction model 108 can be viewed in an exploded format that can separate the assembled project into the various components and products. A few examples of the components and products of the construction model 108 are shown in FIG. 2. As shown, the construction model 108 can include information regarding door 202, wall 204, cladding 206 and the like.

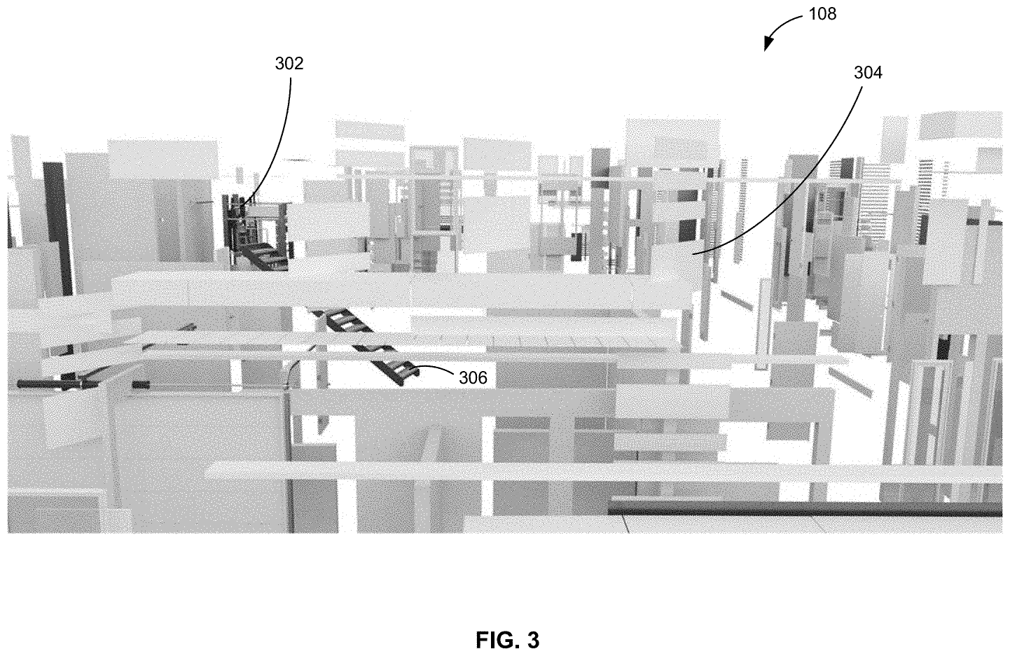

As shown in FIG. 3, the construction model 108 can be further separated and/or viewed in an exploded format to view not only the exterior components and/or products but also the interior components and/or products such as core 302, interior wall 304, staircase 306 and the like.

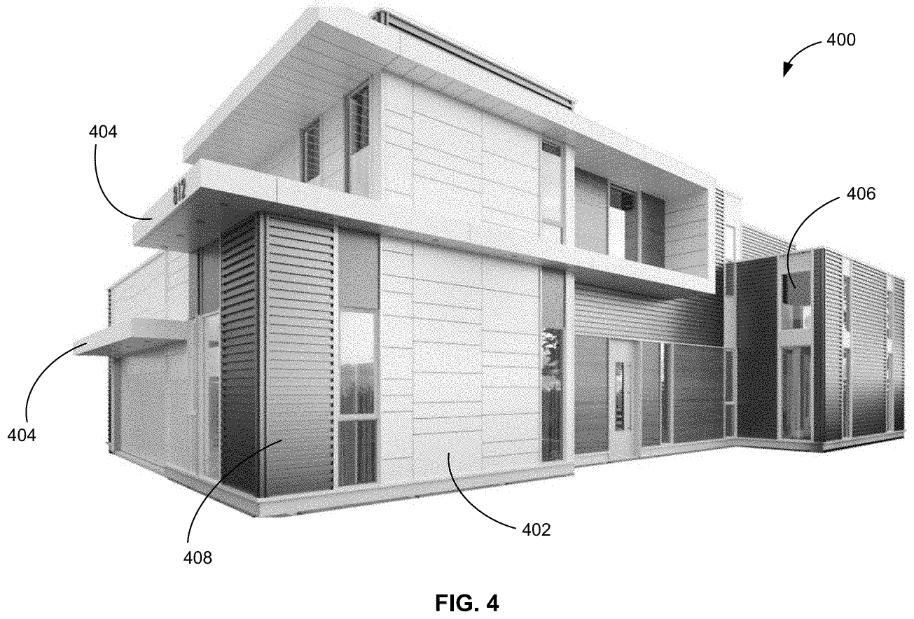

As shown in FIG. 4, an example construction project 400 can be a residential home. The construction project 400 can also be other types of construction projects such as commercial or public buildings or structures. In this example, the construction project 400 can be built using integrated component-based construction (ICBC) technology and components. Integrated component-based construction includes technology, methods and materials that may include a library of components and building processes that standardizes the fabrication and assembly of the construction project 400. Elements of ICBC technology can include standard components, non-standard components and common products.

Standard components can include building components that are proprietary components to the operator of the coordination platform 102. In one example, the standard components can include a library of standard components. The standard components do not change and are typically used in every construction project. There can be more than 100 standard components used on one example of the coordination system 100. Examples of standard components include coping, wall bases, doors, windows, corner trims, rebar matts. Standard components are typically used in the same manner for the same function in various building projects; thus could be inventoried.

Non-standard components are components that are principally the same but may have different design parameters such as different dimensions or different aspects specific to a particular construction project. Non standard components have a unique ID number. The non-standard components may be unique to a specific building project. Because of some of the dimensional characteristics, they often cannot be used in other circumstances. The non-standard components may have to be produced specifically for a building project. However, their family gives them the same consistent characteristics, only with certain dimensional differences. Examples of non-standard components include wall panels, Proto Core, Face Frames, cladding panels, stairs, sill plates, ledger boards, etc.

Common products are products that are commonly used building materials used in many constructions projects. These materials include fasteners, adhesives, sealers, windows and the like that are commonly used in construction projects.

Referring back to FIG. 4, the construction project 400 can include for example a plurality of standard components such as wall panel 402 and siding 408. The construction project 400 may also include non-standard components such as exterior extensions 404. As can be appreciated, the exterior extensions 404 can utilize common elements such as cross-sectional shapes, supports for extending the extensions away from the exterior of the construction project 400 and the like, but may have different lengths (i.e., distances along the exterior of the construction project 400). The construction project 400 can also include common products such as windows 406.

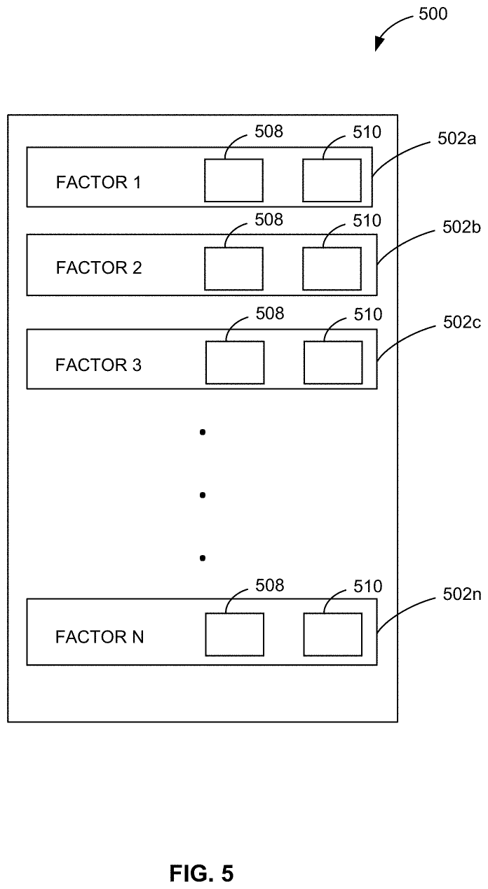

The coordination platform 102 can operate to prepare a construction plan 500. The construction plan 500 can be derived from the construction model 108. Construction plan 500 can include assembly instructions and can be separated into different stages or steps so that each stage of construction. A stage or step of construction can be termed a factor. As shown in FIG. 5, the construction plan 500 can include, in one example, a plurality of factors 502a, 502b, 502c . . . 502n. A factor 502 is a grouping of components, materials and tasks that are performed at a predetermined time during the completion of a construction project. The construction plan 500 can include any number of factors 502 that may be required for completion of a particular construction plan. Factors 502 can be understood to be a particular delineated step of the construction process. Example factors 502 can include for example, Project Kick-off, Footing, Slab, Core, 1st Floor Structure, 2nd Floor Structure, 3rd Floor Structure, Interior Walls and Ceiling, Roofing, Weatherproofing, Interior Doors, Electrical Boxes and Cans, Garage Door, Rough Plumbing, Rough HVAC, Fire Sprinklers, Wiring Electrical, Coping and Wall Base, Arch Projections, Exterior Trim, PVC Cladding, Exterior Painting, Metal Cladding, Accent Cladding, Insulation and Drywall, Tile Work, Interior Painting, Casework and Cabinets, Counter Top, Finish Mechanical, Electrical and Plumbing, Interior Finishes, Appliances, Finish Sprinkler Heads, and Close-out. In other examples, factors 502 can include other steps or stages of construction projects.

Each of the factors 502 above, can include multiple types of information. Each of the factors 502 may include, for example, fabrication information/data 508, and/or assembly information/data 510. The fabrication data 508 can include information that can allow suppliers and/or fulfillment centers to manufacture and/or acquire the materials that are required for a particular factor 502. The fabrication data 508 can include dimensions, materials, quantities, sizes, relationships between components and other information. The fabrication data 508 can also include marking data that indicates to the fulfillment centers and/or suppliers the markings that are to be included on the ICBC components. The assembly data 510 can include information for the construction professionals that describes how the components and products are to be assembled together at the construction site.

Each factor can include its own fabrication data 508 and assembly data 510. In this manner, the components and assembly information can be created and then delivered to the construction site for each factor 502 individually rather than entire loads or amounts of construction materials being shipped and/or delivered to a construction site. This type of step-by-step fabrication, delivery and assembly can simplify the construction process, reduce the likelihood of materials being wasted, stolen or being damaged. Once each factor is completed at the construction site, the next factor 502 can be initiated and then completed. Once all the factors 502 are completed, the construction project is complete.

As discussed above, the coordination platform 102 can determine the construction plan like the construction plan 500 previously described. The coordination platform can use the centralized construction model 108 to determine the various factors 502a to 502n that may be required for a particular construction project. The coordination platform 102 can extract the components for each stage of construction (i.e., each factor 502) and then group the components together for each factor. The use of Integrated Component-Based Construction Components and details thereof are further described in U.S. Pat. Appl. No. TBD, filed on Nov. 16, 2021 entitled INTEGRATED COMPONENT-BASED CONSTRUCTION COMPONENTS AND RELATED METHODS, the entirety of which is hereby incorporated by reference.

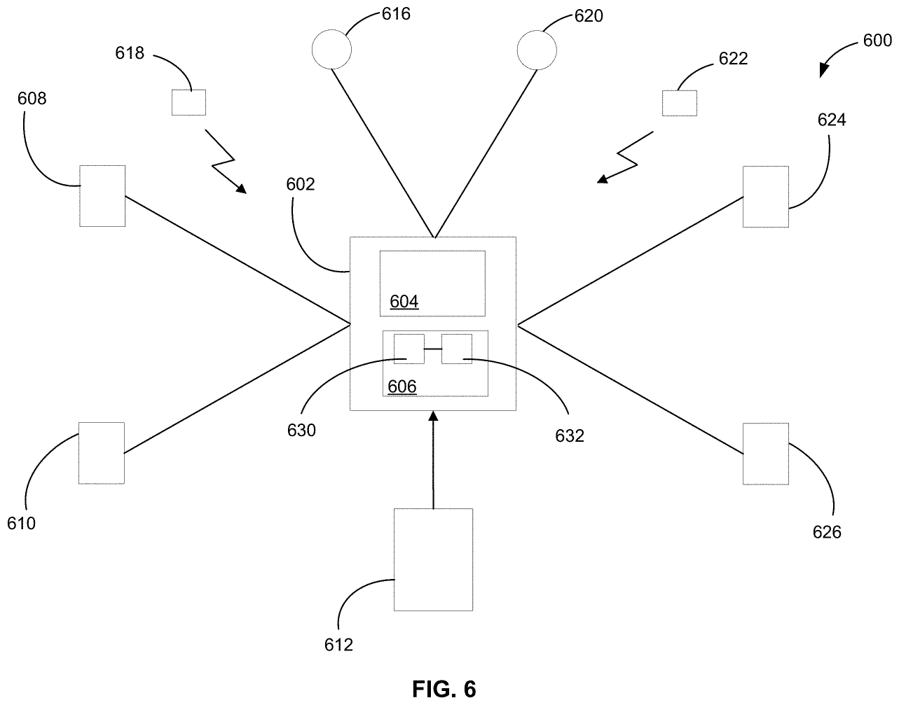

Referring now to FIG. 6, an example integrated whole house electrical system 600 is shown. The electrical system 600 can be installed in a building project using one or more of the methods described herein. The electrical system 600, as will be further explained, can be assembled or installed into a building project, such as building project 130. All the shown elements can be installed or assembled onto or into the building project 130. In some examples, however, an electrical resource input 612 can be located external to the building project 130. The electrical resource input 612 can be source of electrical energy that is coupled to the electrical system 600 and then is distributed to the various components and/or outlets. The electrical resource input 612 can be utility source such from the local power utility company and can be provided via wire to the electrical system 600. In other examples, the electrical resource input 612 can be other suitable electrical energy sources such a battery, solar array, geothermal source, wind source, generator, etc. or combinations thereof.

As shown, the electrical system 600 can include an electrical panel assembly 602, one or more line voltage outlets 608, 610, 624, 626, one or more low voltage components 616, 620 and one or more component controls 618, 622. The electrical panel assembly 602 can be assembled in any suitable manner and as will be described further below is preferably delivered to the building site in a pre-fabricated manner. The coordination platform 102 can build the centralized construction model 108 that can contain all the features and/or characteristics of the building project. Thus, the centralized construction model 108 can include all the electrical aspects of the project. The necessary information and requirements for the electrical panel assembly 102 can be provided to a partner fabricator that can pre-fabricate and deliver the electrical panel assembly 102 to the building site. In other example, the electrical panel assembly 102 can be provide as part of a centralized core that includes multiple resource distribution systems in addition to the electrical panel assembly 102.

The electrical panel assembly 602 can include one or more one or more line voltage source connection points 604 and one or more low voltage power sources 606. These connection points can be integrally mounted to chasses or other support structure. The line voltage connection points 604 can be, in some examples, gang boxes or a centralized gutter box that allow electrical wires to be connected thereto. The line voltage connection point 604 are configured to provide line voltage energy to various places in the building project. Line voltage connection points 604 can provide electrical energy as typically provided in the local geographic that the building project is located. Various countries can have different line voltages. In the United States, the typical line voltage is about 120 volts or about 240 volts. In other countries and other locations other suitable line voltages can be provided.

The line voltage connection points 604 can be coupled to the line voltage outlets 608, 610, 624, 626. The line voltage outlets 608, 610, 624, 626 can be actual outlets positioned in walls or other support structures of the building project can allow various electrical items to be plugged into and powered. Such traditional outlets can be used to power appliances, lamps, and other electronics, for example. The line voltage outlets 608, 610, 624, 626 can also be other types of outlets such a direct wired appliances, or other electronics.

The low voltage connection points 606 can be sources of low voltage electricity at the electrical panel assembly 602. In one example, the low voltage connection points 606 can be suitable low voltage transformers 632 that can take the energy from the electrical resource input 612 can convert the incoming signal to a low voltage electrical signal. Example low voltage electrical signals can include about 12 volt or about 24 volt signals. In other examples, other suitable low voltage signals can be provided.

The low voltage connection points 606 can be multiple transformers 632 mounted in the electrical panel assembly 602, for example. In some examples, each low voltage transformer 632 can be paired with a wireless switch or smart switch 630. The wireless or smart switch 630 can be located in the electrical panel assembly 602 and can operate to allow electricity from the transformers to energize the low voltage components 616, 620. The low voltage connection points 606 can be coupled to the low voltage components 616, 620. The low voltage components can be any suitable electrical devices that operate with the low voltage. The lighting components of the building project, for example, can all operate at low voltage. Therefore, the low voltage components 616, 620 can be overhead can lights, sconces, light fixtures, lamps and the like. The exterior lighting for the building project can also operate as low voltage lighting. Still further, other electronics may operate as low voltage components 616, 620 such as intercoms, security devices, audio systems and the like.

As further shown, the controls 618, 622 can also be provided. The controls 618, 622 can be any suitable computing device, smart phone, touch pad, voice assistant or control pad that can be wirelessly connected to the smart switches 630 in the low voltage connection points 606. As can be appreciated, the control 618 or control 622 can be coupled to multiple connection points 606 as may be desired to provide switching for multiple lights or multiple zones of lights.

The low voltage components 616, 620 can connected to the electrical panel assembly 602 via a direct connection. In such instances, the components 616, 620 can be connected via a home-run wire or by a wire that is not interrupted between the component and the electrical panel assembly 602. This configuration can simply the wiring process by making the installation standardized for the installer and allowing each connection to be clearly marked on the component and/or on the electrical panel assembly. Furthermore, the lack of wires needed to be run between controls 618, 622 and the components 616, 620 further simplifies the wiring process during installation of the electrical system 600.

The connections between the line voltage outlets 608, 610, 624, 626 and the electrical panel assembly 602 can be connected any suitable manner. The connections can be traditional series or parallel connections or also be run as direct connections. The connections can be routed through a common gang box in the electrical panel assembly and can be marked or otherwise identified. This can simplify the wiring and/or installation process and can allow the line voltage outlets 608, 610, 624, 626 and/or the electrical panel assembly 602 to be easily installed.

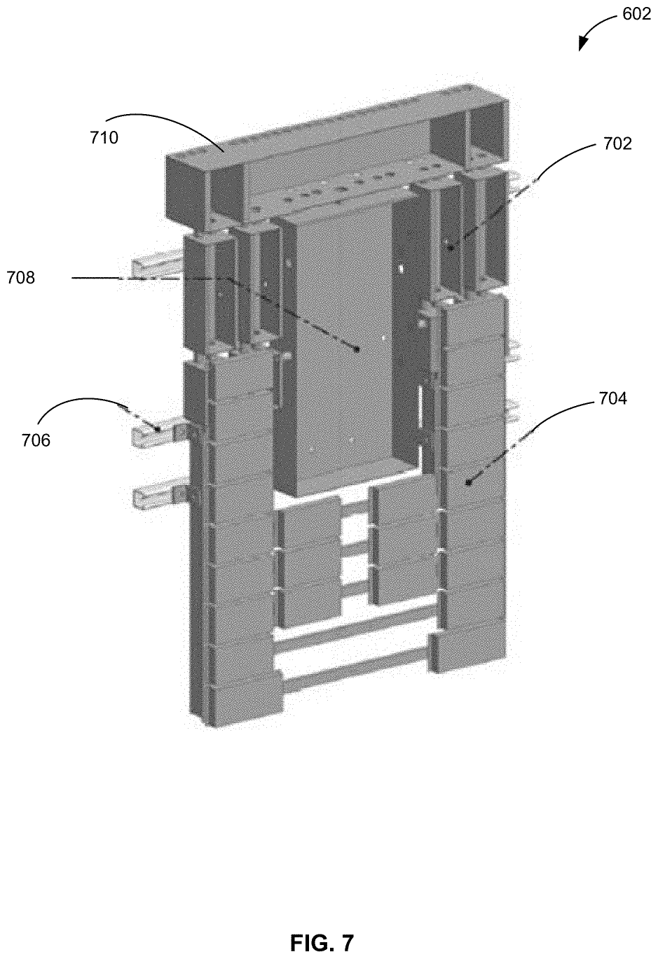

As shown in FIG. 7, aspects of an example electrical panel assembly 602 is shown. While some the elements are not shown, the general structure and housing of the panel assembly 602 are represented. As shown, the panel assembly 602 can include a housing 708, one or more gang boxes 702, one or more low voltage transformers 704 that are mounted on a chassis 706. The chassis 706 can include one or more support members such as lengths of lumber, channels, tubing or the like. The chassis 706 provides a support structure to allow the other elements of the electrical panel assembly to be mounted or supported next to each other or on a predetermined wall of the building project. The electrical panel assembly 602 can arrive at the building site in a pre-fabricated manner and mounted on the chassis 706 as shown.

The housing 708 can be a metal, plastic or other material enclosure that is suitable for the mounting of various electrical elements such as circuit breakers, electrical connectors and the like. The housing 708 can include one more openings or other suitable connectors that can allow the electrical resource input 612 to be connected to the electrical panel assembly 602. The electricity can then be distributed from the housing 708 as needed to the various other components of the electrical panel assembly 602. The gutter boxes 710 are an example of the line voltage connection points previously described. The gutter boxes 710 can be positioned at a top of the housing 708 or otherwise adjacent to housing 708. The gutter boxes 710 can constructed of suitable metallic, plastic or composite material and can include openings and/or connectors to allow wires to passed into and out of the gang boxes. The direct connections from the line voltage outlets can be connected to the gang boxes 702. In this example, two gang boxes 702 are mounted on the chassis 706 on either side of the housing 708. In other examples, other configurations can be used. The gutter boxes 710 can include suitable markings that identify connections for other electrical components to the electrical panel assembly 602.

The electrical panel assembly 602 can also include many low voltage transformers 704. The low voltage transformers 704 can operate as part of the low voltage connection points previously described. The low voltage transformers 704 can be electrically coupled to the housing 708 and to the electric resource input. The low voltage transformers 704 can then be connected to the low voltage components as previously described. As can be seen, the electrical panel assembly 602 can include several rows of low voltage transformers 704. The number of low voltage transformers 704 will vary depending on the requirements of the building project and can be determined using the centralized construction model 108. In the example shown, the electrical panel assembly 602 include twenty four low voltage transformers 704. In other examples, the electrical panel assembly 602 can include more than twenty four transformers and in others, less than twenty four transformers.

Electrical smart switches can be paired and coupled to the low voltage transformers 704. The electrical smart switches can be mounted in the gang boxes 702 of the electrical panel assembly 602. Any suitable smart switches can be used. In some examples, the smart switches are wireless switches that can operate to selectively allow electricity to pass from a low voltage transformer 704 to a low voltage component. In this manner, the smart switches can operate to turn off or turn on the low voltage components. The smart switches, in some examples, can also provide the capability to dim lighting as may be desired. The wireless switches can operate using any suitable wireless frequency or signal. In some examples, a wifi, Bluetooth, Zigbee, Z-wave or other wireless standard can be used.

Various control devices can then be used to communicate with the smart switches to control the low voltage components that are connected to the low voltage transformers. Such control devices can include, for example, computing devices, laptops, smart phones, touch pads, control pads, voice assistants, remote controls, and the like. In some examples, the wiring for the low voltage components can be routed through the gutter box 710. In addition, the gutter box 710 can include markings to identify the low voltage components and/or related wiring that is connected to the electrical panel assembly 602.

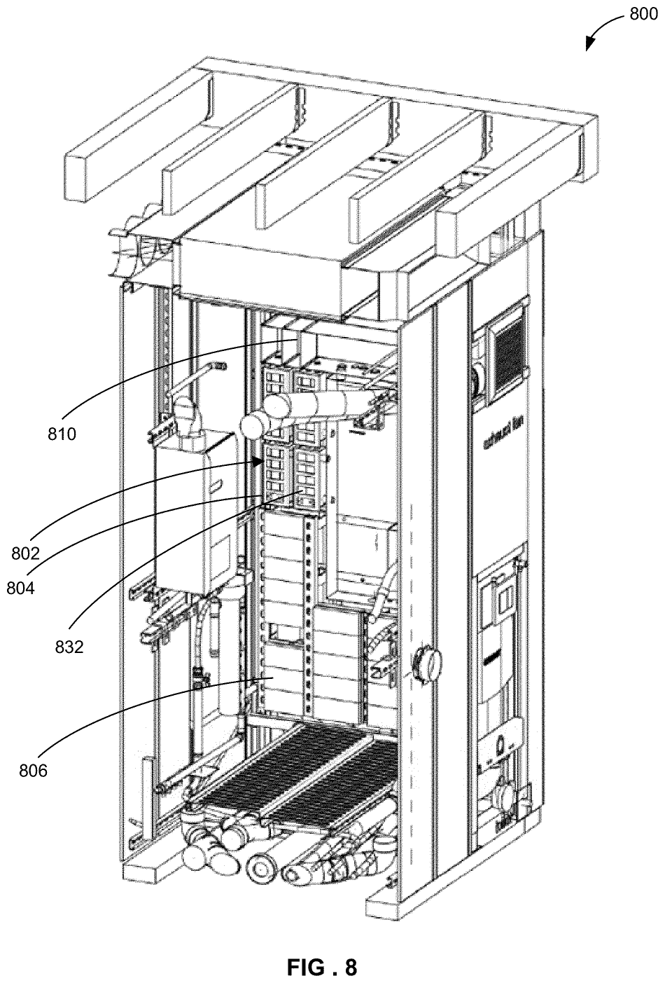

As shown in FIG. 8, the electrical panel assembly 602 can be positioned in a centralized core 800. Further details of the core 800 and related methods are described in U.S. Pat. Appl. No. TBD entitled CENTRALIZED CORE AND NODE SYSTEM FOR CONSTRUCTION PROJECTS filed on Nov. 16, 2021, the contents of which are hereby incorporated by reference in its entirety.

As can be seen, the electrical panel assembly 802 can be delivered as part of the centralized core 800. The electrical panel assembly 802 can be similar to the electrical panel assembly 602 previously described. As can be seen, the electrical panel assembly 802 can include gutter box 810, gang boxes 804, wireless smart switches 832, and low voltage transformers 806. The chassis of the electrical panel assembly 802, while not visible in this illustration, can be mounted to a wall or side of the core 800. As shown in this example, the wireless smart switches 832 are mounted in the gang boxes 804. The smart switches 832 can be coupled to the low voltage transformers 806 as previously described. The gutter box 801 can be the routing location through which the direct connections or wires from the low voltage components can be routed from other locations in the building project. In some examples, the line voltage outlets can also be routed through the gutter box 810. The gutter box 810, the smart switches 832 and the low voltage transformers 806 can all be suitably marked or labeled with identifying information that indicates the connections that are to made during assembly of the building project. The electrical panel assembly 802 can be accessible by a technician or builder by accessing the interior space of the core 800.

As can be further appreciated, the electrical systems and electrical panel assemblies disclosed above support various construction methods and assemblies with improvements over existing construction technologies. In one example method, the core 800 can be delivered to a building site in a pre-fabricated form. Thus, the electrical panel assembly 802 is pre-fabricated as well and delivered to the building site (with the core 800) in an assembled form. The construction of the building project can continue with wall sections, ceilings, exterior panels and the like being installed during their respective factors. The wiring can be installed before the wall sections finished. The wiring can be installed as direct or home-run lines from the line voltage outlets and from the low voltage components to the core 800 and to the electrical panel assembly 802. The centralized construction model can provide all the necessary information for such connections and wiring. Furthermore, the line voltage outlets, the low voltage components as well as the electrical panel assembly can include markings or labels to clearly identify and instruct the building to make the appropriate connections between elements. The wireless switches can also be connected and paired with the identified low voltage components. In this manner, the electrical systems and the electrical panel assemblies of the present disclosure can be installed without consulting electrical schematics, zoning requirements or architectural drawings. For this reason, at least, the systems, methods and assemblies of the present disclosure are improvements over traditional building processes.

The example methods and apparatuses described herein may be at least partially embodied in the form of computer-implemented processes and apparatus for practicing those processes and/or the described functionality. The disclosed methods may also be at least partially embodied in the form of tangible, non-transient machine readable storage media encoded with computer program code. The media may include, for example, RAMs, ROMs, CD-ROMs, DVD-ROMs, BD-ROMs, hard disk drives, flash memories, or any other non-transient machine-readable storage medium, or any combination of these mediums, wherein, when the computer program code is loaded into and executed by a computer, the computer becomes an apparatus for practicing the method. The methods may also be at least partially embodied in the form of a computer into which computer program code is loaded and/or executed, such that, the computer becomes an apparatus for practicing the methods. When implemented on a general-purpose processor, the computer program code segments configure the processor to create specific logic circuits. The methods may alternatively be at least partially embodied in a digital signal processor formed of application specific integrated circuits for performing the methods.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. An electrical system for installation in a building project comprising:
an electrical panel assembly comprising a chassis and at least one housing;
one or more line voltage source connection points mounted to the chassis; and
one or more low voltage power sources mounted to the chassis;
wherein the electrical panel assembly is located in a predetermined location in the building project for connection to one or more low voltage components via direct connections and to one or more line voltage outlets.

2. The electrical system of claim 1, wherein the direct connections to the low voltage components are home-run connections.

3. The electrical system of claim 1, wherein the at least one housing is configured to receive an electrical input from an exterior of the building project and the electrical system further comprises one or more wireless smart switches mounted to the chassis and coupled to the one or more low voltage power sources.

4. The electrical system of claim 1, wherein the at least one housing is configured to receive an electrical input from an exterior of the building project and the one or more low voltage power sources comprise one or more transformers electrically coupled to the electrical input.

5. The electrical system of claim 1, wherein the line voltage source connection points provide an electrical voltage of about 120 volts or about 240 volts.

6. The electrical system of claim 1, wherein the low voltage power sources provide an electrical voltage of about 12 volts or about 24 volts.

7. The electrical system of claim 1, wherein the predetermined location in the building project comprises a location of a pre-fabricated core and the electrical panel assembly is a pre-fabricated assembly that is delivered to the building project as part of the pre-fabricated core that includes one or more other distribution systems for the building project.

8. The electrical system of claim 1, wherein each of the direct connections comprises a length of wire that extends from one of the one or more low voltage components to the electrical panel assembly without interruption.

9. The electrical system of claim 1, wherein the one or more low voltage components comprises one or more low voltage lights.

10. The electrical system of claim 1, further comprising one or more wireless switches mounted to the chassis and coupled to the one or more low voltage components.

11. The electrical system of claim 1, further comprising a battery coupled to the electrical panel assembly configured to energize the one or more low voltage components.

12. A pre-fabricated electrical panel assembly comprising:
a chassis;
an electrical resource input receptacle mounted to the chassis and configured to receive an electrical resource input to provide electrical power to a building project;
one or more line voltage source connection points mounted to the chassis and electrically coupled to the electrical resource input receptacle; and
one or more low voltage power sources mounted to the chassis and electrically coupled to the electrical resource input receptacle and configured for direct connection of a low voltage component.

13. The pre-fabricated electrical panel assembly of claim 12, wherein the direct connection of the low voltage component comprises an uninterrupted wire connected between the low voltage component and the electrical panel assembly.

14. The pre-fabricated electrical panel assembly of claim 13, further comprising one or more wireless smart switches coupled to the one or more low voltage power sources.

15. The pre-fabricated electrical panel assembly of claim 14, wherein the one or more wireless smart switches are mounted to the chassis.

16. The pre-fabricated electrical panel assembly of claim 15, wherein no low voltage components are connected to the electrical panel assembly via an indirect connection.

17. The prefabricated electrical panel assembly of claim 12, wherein the chassis comprises one or more support members and is configured to mount to a wall of a predetermined size.

18. A building project comprising an electrical system to provide line voltage outlets and low voltage lighting, the building project comprising:
a pre-fabricated electrical panel assembly comprising a plurality of line voltage connection points, a plurality of wireless switches and a plurality of low voltage transformers;
a plurality of line voltage outlets each connected to one of the plurality of line voltage connection points; and
a plurality of low voltage lighting components each connected to one of the plurality of low voltage transformers via direct electrical connections.

19. The building project of claim 18, wherein the pre-fabricated electrical panel assembly is assembled prior to delivery to a building site for the building project.

20. The building project of claim 19, wherein the building project does not include a low voltage lighting component that is connected to the electrical panel assembly via an indirect connection.
